(19) United States
(12) Patent Application Publication
(10) Pub. No.: US 2015/0270308 A1
(43) Pub. Date: Sep. 24, 2015

(54) CMOS IMAGE SENSOR AND METHOD OF MANUFACTURING THE SAME

(71) Applicant: Sun CHOI, Icheon-si (KR)

(72) Inventor: Sun CHOI, Icheon-si (KR)

(73) Assignee: DONGBU HITEK CO., LTD., Seoul (KR)

(21) Appl. No.: 14/453,028

(22) Filed: Aug. 6, 2014

(30) Foreign Application Priority Data
Mar. 18, 2014 (KR) 10-2014-0031426

(51) Int. Cl. H01L 27/146

(52) U.S. Cl. CPC H01L 27/14645; H01L 27/14689; H01L 27/14612; H01L 27/14621; H01L 27/14636; H01L 27/1463; H01L 27/14625; H01L 27/14627; H01L 27/14685

(57) ABSTRACT

A complementary metal-oxide-semiconductor (CMOS) image sensor includes a substrate including a photodiode, a transistor on the substrate; a first insulating layer on the substrate; a contact connected to the transistor and passing through the first insulating layer; an etch stop layer on the first insulating layer; a second insulating layer on the etch stop layer; and a signal line extending through the etch stop layer and the second insulating layer, on the first insulating layer and connected to the contact.

### CROSS-REFERENCE TO RELATED APPLICATION

This application claims priority to Korean Patent Application No. 10-2014-0031426, filed on Mar. 18, 2014, and all the benefits accruing therefrom under 35 U.S.C. §119, the contents of which are incorporated by reference in their entirety.

### BACKGROUND

The present disclosure relates to an image sensor and a method of manufacturing the same. In more detail, the present disclosure relates to a complementary metal-oxide-semiconductor (CMOS) image sensor and a method of manufacturing the same.

In general, an image sensor is a semiconductor device that converts an optical image into electrical signals, and may be classified or categorized as a charge coupled device (CCD) or a CMOS image sensor (CIS).

The CMOS image sensor includes unit pixels, each including a photodiode and MOS transistors. The CMOS image sensor sequentially detects the electrical signals of the unit pixels using a switching method, thereby forming an image.

The CMOS image sensor is made by forming photodiodes in or on a semiconductor substrate, forming transistors connected to the photodiodes on the semiconductor substrate, forming wiring layers functioning as signal lines connected to the transistors, and forming a color filter layer and micro lenses on or over the wiring layers.

Especially, a first insulating layer may be formed on the photodiodes and the transistors, and both (1) signal lines connected to the transistors and (2) a second insulating layer may then be formed on the first insulating layer. Additionally, a plurality of interlayer insulating layers and a plurality of wiring layers may be formed on the second insulating layer, and the color filter layer and the micro lenses may then be formed on the uppermost interlayer insulating layer.

The signal lines may be connected to the transistors through contact plugs penetrating the first insulating layer. The contact plugs and the signal lines may be formed using a damascene process. Especially, the second insulating layer may be formed on the first insulating layer and the contact plugs, and then trenches exposing the contact plugs may be formed by removing predetermined parts of the second insulating layer. The signal lines may be formed by filling the trenches with a conductive material.

Meanwhile, during an etching process for removing predetermined parts of the second insulating layer to form the trenches, an etch rate may vary between the center and edge regions of a wafer used as the semiconductor substrate. Accordingly, the depth uniformity of the trenches may be less than ideal. As a result, the electrical resistances of the signal lines in the trenches may become non-uniform, and thus the characteristics of CMOS image sensors formed on the wafer may be non-uniform.

### SUMMARY

The present disclosure provides a method of manufacturing a CMOS image sensor capable of making the electrical resistances of signal lines connected to transistors more uniform, and a CMOS image sensor manufactured using the method.

In accordance with one or more exemplary embodiments, a complementary metal-oxide-semiconductor (CMOS) image sensor may include a substrate including a photodiode; a transistor on the substrate; a first insulating layer on the substrate; a contact connected to the transistor and passing through the first insulating layer; an etch stop layer on the first insulating layer; a second insulating layer on the etch stop layer; and a signal line extending through the etch stop layer and the second insulating layer, on the first insulating layer and connected to the contact. Some embodiments of the CMOS image sensor may include a plurality of unit pixels, where each unit pixel includes the above structure. Each unit pixel may include a plurality of transistors on the substrate, and the first insulating layer may be on the substrate and the plurality of transistors.

The etch stop layer may include silicon nitride.

The etch stop layer may have a thickness of about 200 Å to about 400 Å.

The sensor may further include a plurality of further insulating layers on the second insulating layer; and at least one wiring layer between adjacent ones of the further insulating layers.

The sensor may further include an optical guide on the first insulating layer. The optical guide may pass through the further insulating layers, the second insulating layer and the etch stop layer, and may correspond to the photodiode. That is, the optical guide may be over the photodiode. The region of the sensor including the optical guide may include no wiring layers or contacts.

The sensor may further include a protective layer on the optical guide; a color filter layer on the protective layer; a planarization layer on the color filter layer; and a micro lens on the planarization layer.

The optical guide may include a metal oxide having a higher refractive index than the further insulating layers.

In accordance with one or more other exemplary embodiments, a method of manufacturing a CMOS image sensor may include forming a photodiode in or on a substrate; forming a transistor on the substrate; forming a first insulating layer on the photodiode and the transistor; forming a contact connected to the transistor through the first insulating layer; sequentially forming an etch stop layer and a second insulating layer on the first insulating layer and the contact; forming a trench exposing the contact; and forming a signal line by filling the trench. In typical embodiments, the trench is formed through the second insulating layer and the etch stop layer in predetermined areas over the transistor(s).

The etch stop layer may include silicon nitride.

The etch stop layer may have a thickness of about 200 Å to about 400 Å.

The first insulating layer may have a thickness of about 4000 Å.

The method may further include forming a plurality of further insulating layers on the second insulating layer and the signal line; and forming at least one wiring layer on a lower one of the further insulating layers before forming an upper one of the further insulating layers (e.g., on the wiring layer[s] and the lower one of the further insulating layers).

The method may further include forming an opening exposing the first insulating layer by removing the further insulating layers, the second insulating layer and the etch stop layer in a predetermined region (e.g., corresponding to or over the photodiode); and forming an optical guide by filling the opening with a light transmitting material.

The method may further include forming a protective layer on the optical guide; forming a color filter on the protective layer; forming a planarization layer on the color filter layer; and forming a micro lens on the planarization layer.

The optical guide may include a metal oxide having a higher refractive index than a material of the further insulating layers.

The method may further include forming a p-type region at or in a surface portion of the substrate before forming the photodiode and/or the transistor.

In accordance with one or more further exemplary embodiments, a method of manufacturing a CMOS image sensor includes forming a photodiode in or on a substrate and a transistor on the substrate; sequentially forming a first insulating layer, an etch stop layer, and a second insulating layer on the photodiode and the transistor; forming a trench exposing the first insulating layer by removing the second insulating layer and the etch stop layer in a predetermined area; forming a contact hole exposing the transistor by removing a portion of the exposed first insulating layer; and forming a contact and a signal line connected to the transistor by filling the contact hole and the trench with a conductive material.

### BRIEF DESCRIPTION OF THE DRAWINGS

Exemplary embodiments can be understood in more detail from the following description taken in conjunction with the accompanying drawings, in which:

FIG. 1 is a sectional view illustrating an exemplary CMOS image sensor according to one or more embodiments of the present invention;

FIGS. 2 to 8 are sectional views illustrating an exemplary method of manufacturing the CMOS image sensor as shown in FIG. 1;

FIG. 9 is a block diagram illustrating operations of the exemplary CMOS image sensor as shown in FIG. 1; and

FIG. 10 is a block diagram illustrating a processor based system including the exemplary CMOS image sensor as shown in FIG. 9.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

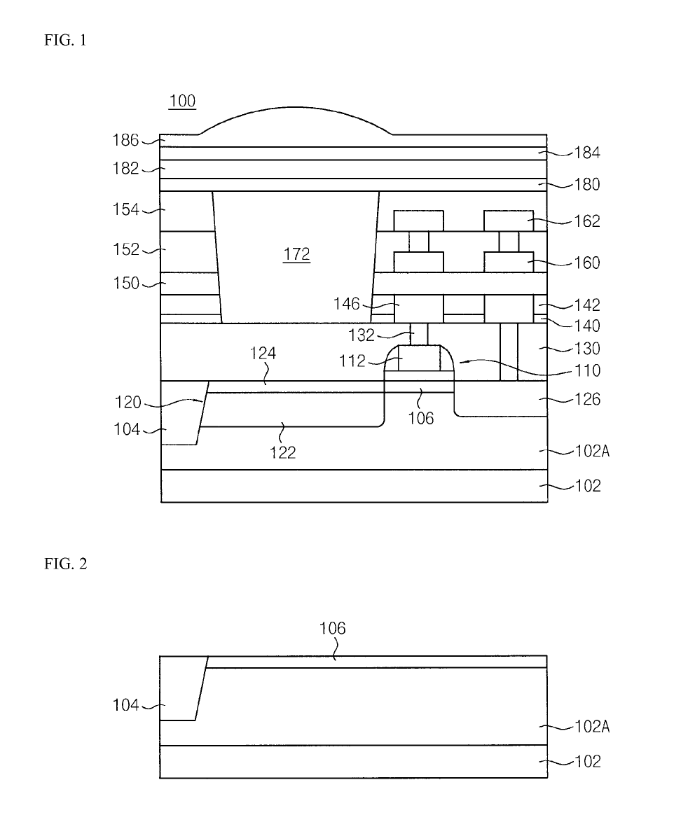

FIG. 1 is a cross-sectional view illustrating an exemplary CMOS image sensor according to one or more embodiments of the present invention.

Referring to FIG. 1, according to one or more embodiments of the present invention, the CMOS image sensor includes a plurality of photodiodes 120 for detecting light and a plurality of transistors 110 electrically connected to the photodiodes 120. Especially, the CMOS image sensor 100 may include a plurality of pixel regions, and each pixel region generally includes a photodiode 120 and a transfer transistor 110 connected to the photodiode 120.

The pixel regions may be electrically separated from each other by a device isolation region 104, and the substrate 102 may have a first conductivity type or include a first conductivity type region or layer, for example, a p-type silicon epitaxial layer 102A as shown in FIG. 1, on a single-crystal silicon wafer (not shown).

The photodiode 120 may be formed at or in a surface portion of the substrate 102, and the transfer transistor 110 may include a transfer gate 112 formed on the substrate 102. The photodiode 120 may be on one side of the transfer gate 112, and a floating diffusion region (FD) 126 may be on another (e.g., opposite) side of the transfer gate 112. Additionally, although not shown in the drawings, the CMOS image sensor 100 may further include a reset transistor and a driving transistor connected to the floating diffusion region 126 and a select transistor connected to the driving transistor.

Although not shown in detail, the photodiode 120 may include a p-type region 124 and an n-type region 122 below the p-type region 124. The floating diffusion region 126 may be an n-type region.

A gate oxide layer may be between the substrate 102 and the transfer gate 112, and the transfer gate 112 may comprise doped polysilicon and/or metal silicide. Additionally, the transfer gate 112 may include spacers comprising an insulating material, and a capping layer may be on the transfer gate 112.

A first insulating layer 130 may be formed on the photodiode 120 and the transfer transistor 110, and a plurality of contacts 132 connected to the transistors 110 and passing through the first insulating layer 130 may be formed. For example, as shown in FIG. 1, a contact 132 connected to the transfer gate 112 and a contact connected to the floating diffusion region 126 may be formed. Additionally, although not shown in the drawings, the CMOS image sensor 100 may include contacts connected to the reset transistor, the driving transistor and the select transistor, which are on the substrate 102.

An etch stop layer 140 and a second insulating layer 142 may be formed or deposited on the first insulating layer 130, and signal lines 146 may be formed on the first insulating layer 130. The signal lines 146 may extend through the etch stop layer 140 and the second insulating layer 142, contact the first insulating layer 130, and be connected to the contacts 132.

Additionally, a plurality of further insulating layers (e.g., interlayer insulating layers) 150, 152 and 154 and wiring layers 160 and 162 may be formed on or over the second insulating layer 142. For example, a first interlayer insulating layer 150 may be formed or deposited on the second insulating layer 142, and a first wiring layer 160 may be formed or disposed on the first interlayer insulating layer 150. A second interlayer insulating layer 152 may be formed or deposited on the first interlayer insulating layer 150 and the first wiring layer 160, and a second wiring layer 162 may be formed or disposed on the second interlayer insulating layer 152. Additionally, a third interlayer insulating layer 154 may be formed or deposited on the second interlayer insulating layer 152 and the second wiring layer 162.

The first and second wiring layers 160 and 162 may include a plurality of power lines and a plurality of data lines. Although not shown in detail, the first and second wiring layers 160 and 162 may be connected to the signal lines 146 through vias and/or contacts, and also the first and second wiring layers 160 and 162 may be connected to a logic region of the CMOS image sensor 100.

Additionally, the CMOS image sensor 100 according to one or more embodiments of the present invention may include optical guides 172 penetrating the interlayer insulating layers 150, 152 and 154, the second insulating layer 142, and the etch stop layer 140. For example, the optical guide 172 may be formed in a region of the CMOS image sensor over the photodiode 120. Especially, the optical guide 172 may be formed on the first insulating layer 130 and may penetrate the etch stop layer 140, the second insulating layer 142, and the interlayer insulating layers 150, 152 and 154. The optical guide 172 may improve the sensitivity of and reduce the crosstalk in the CMOS image sensor 100.

A protective layer 180 and a color filter layer 182 may be formed on the third interlayer insulating layer 154, and further, a planarization layer 184 and a plurality of micro lenses 186 may be formed on the color filter layer 182.

FIGS. 2 to 8 are cross-sectional views illustrating an exemplary method of manufacturing the CMOS image sensor as shown in FIG. 1.

Referring to FIG. 2, a substrate 102 including a first conductive type (for example, a p-type) epitaxial layer 102 or a p-type substrate may be prepared or obtained. Device isolation regions 104 may be formed at or in surface portions of the substrate 102. The device isolation regions 104 generally separate pixel regions from each other. For example, trenches (not shown) may be formed at or in surface portions of the substrate 102 (e.g., of the p-type epitaxial layer 102A) using an etching process, and the device isolation regions 104 may be formed by filling the trenches with an insulating material, for example, a silicon oxide using a high density plasma (HDP) deposition technique.

Then, a p-type region 106 may be formed at, in or on a surface portion of the substrate 102. The p-type region may adjust the threshold voltage of the transfer transistor 110 (e.g., in a channel region below a transfer gate), and may reduce noise and dark current in the photodiode 120.

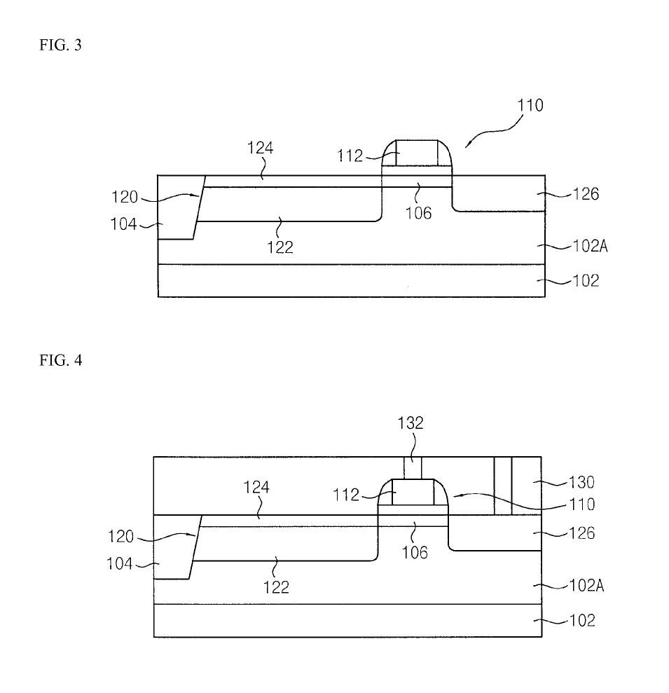

Referring to FIG. 3, after forming the p-type region 106, a plurality of gates 112 may be formed on the substrate 102. For example, a gate insulating layer, a gate conductive layer and a gate capping layer may be formed on the substrate 102, and the gate capping layer, the gate conductive layer and the gate insulating layer may then be patterned to form the gates 112 on the substrate 102.

After forming the gates, a photodiode 120 may be formed on one side of the transfer gate 112. For example, by forming an n-type region 122 at or in a surface portion of the substrate 102 and forming a p-type region 124 on or in the n-type region 122 using an ion implantation process, a pinned photodiode may be formed.

After forming the photodiode 122, an n-type region functioning as the floating diffusion region 126 may be formed on another side of the transfer gate 112 using an ion implantation process. As a result, the transfer transistor 110 including the transfer gate 112, the photodiode 120, and the floating diffusion region 126 may be formed in the pixel region.

The source/drain regions of the reset transistor, the driving transistor and the select transistor may be formed at the same time as the floating diffusion region 126.

Meanwhile, the gates may include spacers (e.g., on sidewalls thereof). The spacers may comprise a silicon oxide and/or a silicon nitride, and may be formed before or after forming the photodiode 120 and the floating diffusion region 126.

Referring to FIG. 4, a first insulating layer 130 may be formed on the photodiode 120 and the transistors 110. The first insulating layer 130 may be or comprise a silicon oxide layer (e.g., silicon dioxide, a TEOS-based silicon oxide, etc.). For example, the first insulating layer 130 may comprise undoped silicate glass (USG), a fluorinated silicate glass (FSG) and/or a borophosphosilicate glass (BPSG), and may be formed by spin coating and curing a hydrogen silsesquioxane (HSQ)-based material or liquid.

The first insulating layer 130 may have a thickness of approximately 2000 Å to approximately 4000 Å. For example, the first insulating layer 130 may have a thickness of approximately 4000 Å.

Then, contact holes (not shown) exposing the transistors 110 may be formed by removing the first insulating layer 130 in predetermined locations. For example, the contact holes may be formed using an anisotropic etching process using a photoresist pattern as an etch mask. After forming the contact holes, the photoresist pattern may be removed using an ashing and/or stripping process.

A conductive material layer may be formed on the first insulating layer 130 to fill the contact holes. For example, the conductive material layer may comprise tungsten (W) and may be formed or deposited using chemical vapor deposition.

Excess conductive material layer on the first insulating layer 130 may be removed using a chemical mechanical polishing process. The chemical mechanical polishing process may be performed until the first insulating layer 130 is exposed to thereby obtain contacts 132 connected to the transistors 110 and passing through the first insulating layer 130.

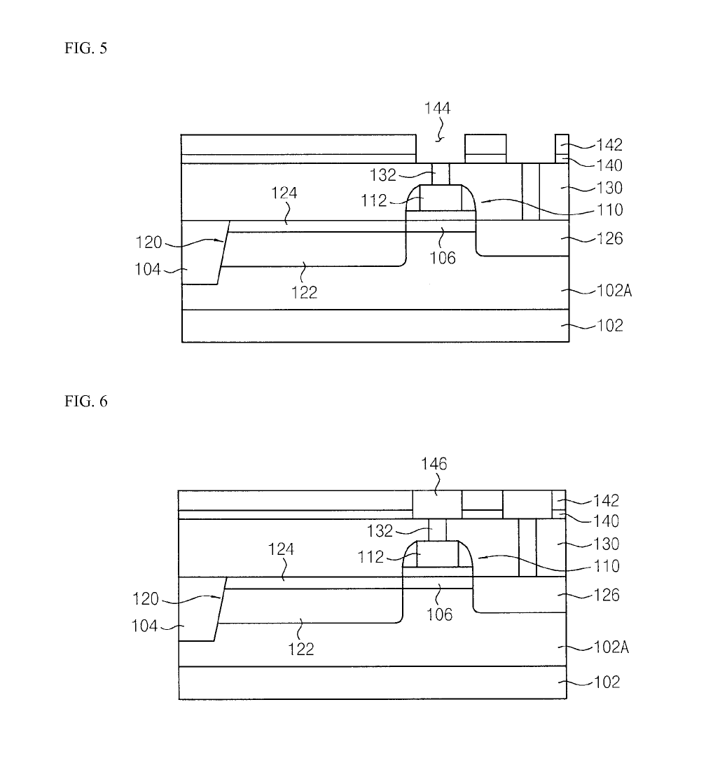

Referring to FIG. 5, after forming the first insulating layer 130 and the contacts 132, an etch stop layer 140 may be formed on the first insulating layer 130 and the contacts 132. The etch stop layer 140 may be or comprise silicon nitride and may be formed using chemical vapor deposition. For example, the etch stop layer 140 may have a thickness of approximately 200 Å to approximately 400 Å and be formed using a low pressure chemical vapor deposition process using a silicon source gas (such as SiH₄ or SiH₂Cl₂) and a nitrogen source gas (such as NH₃). Especially, the etch stop layer 140 may have a thickness of approximately 300 Å.

A second insulating layer 142 may be formed on the etch stop layer 140. The second insulating layer 142 may comprise a silicon oxide and may have a thickness of thousands of A. The second insulating layer 142 may be deposited by chemical vapor deposition. The second insulating layer 142 may be or comprise the same material(s) as the first insulating layer 130.

By forming a photoresist pattern on the second insulating layer 142 and performing an anisotropic etching process using the photoresist pattern as an etch mask, trenches 144 exposing the contacts 132 may be formed. Etch uniformity may be improved by the etch stop layer 140 during the anisotropic etching process. In more detail, during the anisotropic etching process, an etch rate difference between the center and edge portions of the substrate 102 may be reduced or negated by the etch stop layer 140, which is etched at a much lower rate than the second insulating layer 142 (e.g., 10-100 times lower), thereby enabling an overetch of the second insulating layer 142 until the thickest part(s) of the second insulating layer 142 are completely etched. Since the etch stop layer 140 is relatively thin and has a relatively uniform thickness across the substrate (e.g., in comparison with the second insulating layer 142), a selective etch of the etch stop layer 140 can be conducted using a timed anisotropic etch or a timed wet etch, thereby cleanly and uniformly removing the second insulating layer 142 and the etch stop layer 140, thus improving the depth uniformity of the trenches 144.

Referring to FIG. 6, after forming the trenches 144, a conductive material layer (not shown) is formed or deposited on the second insulating layer 142 to fill the trenches 144. For example, the conductive material layer may comprise tungsten (W) or aluminum (Al), and may be formed or deposited by chemical vapor deposition. One or more adhesive and/or diffusion barrier layers comprising Ti and/or TiN may be formed or deposited first, before the conductive material.

After forming the conductive material layer as above, a chemical mechanical polishing process may be performed to expose the second insulating layer 142, thereby obtaining signal lines 146 connected to the contacts 132.

According to one or more other embodiments of the present invention, the contacts 132 and the signal lines 146 may be formed using a dual damascene process. For example, the first insulating layer 130, the etch stop layer 140, and the second insulating layer 142 may be sequentially formed on the photodiode 120 and the transistors 110. Thereafter, the trenches 144 may be formed using an anisotropic etching process using a first photoresist pattern as an etch mask, and then the contact holes may be formed using another anisotropic etching process using a second photoresist pattern as an etch mask. Then, by filling the contact holes and the trenches 144 with a conductive material, the contacts 132 and the signal lines 146 may be formed simultaneously.

When a dual damascene process is performed as above, during the anisotropic etching process for forming the trenches 144, the depth uniformity of the trenches 144 may be greatly improved by the etch stop layer 140.

According to the above-mentioned embodiments of the present invention, since the depth uniformity of the trenches 144 is improved using the etch stop layer 140, the thicknesses of the signal lines 146 formed in the trenches may become more uniform. As a result, the electrical resistances of the signal lines 146 become more uniform, and the characteristic(s) of the CMOS image sensors 100 formed on the substrate 102 may be improved.

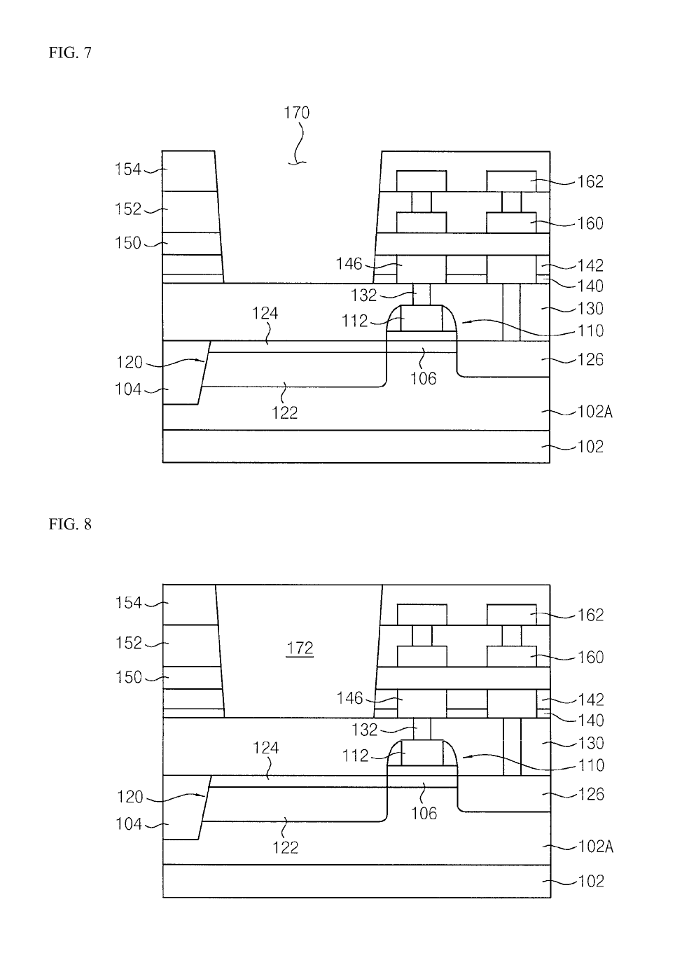

Referring to FIGS. 7 and 8, a plurality of further (e.g., interlayer) insulating layers 150, 152, and 154 and wiring layers 160 and 162 may be alternately formed on the second insulating layer 142 and the signal lines 146. For example, a first interlayer insulating layer 150 may be formed or deposited on the second insulating layer 142 and the signal lines 146, and the first wiring layer 160 may be formed on the first interlayer insulating layer 150. The second interlayer insulating layer 152 may be formed or deposited on the first interlayer insulating layer 150 and the first wiring layer 160, and the second wiring layer 162 may be formed on the second interlayer insulating layer 152. Then the third interlayer insulating layer 154 may be formed or deposited on the second interlayer insulating layer 152 and the second wiring layer 162. The interlayer insulating layers 150, 152, and 154 may comprise a silicon oxide, and the wiring layers 160 and 162 may comprise tungsten (W) or aluminum (Al).

According to one or more embodiments of the present invention, openings 170 exposing the first insulating layer 130 may be formed through the interlayer insulating layers 150, 152, and 154, the second insulating layer 142 and the etch stop layer 140. Optical guides 172 may be formed in the opening 170 by filling the openings 170 with a light transmitting material.

The optical guides 172 may correspond to the photodiodes 120 (that is, be located over the photodiodes 120) to improve the sensitivity of and/or reduce crosstalk in the CMOS image sensors 100.

Especially, during an anisotropic etching process for forming the openings 170, the etch uniformity may be improved by the etch stop layer 140 in substantially the same way as for the trenches 144 in the second insulating layer 142 (see FIG. 5), and as a result, the thickness of the first insulating layer 130 between the photodiodes 120 and the optical guides 172 may be maintained and/or be relatively uniform.

Moreover, the optical guides 172 may be formed by filling the openings 170 with a light transmitting material layer and then removing excess light transmitting material layer on the third interlayer insulating layer 154 using chemical mechanical polishing or an etch-back process. The light transmitting material layer may have a higher refractive index than one or more materials of the interlayer insulating layers 150, 152 and 154 (e.g., the silicon oxide-based materials of the interlayer insulating layers 150, 152 and 154). For example, a metal oxide such as titanium oxide, aluminum oxide, hafnium oxide, zirconium oxide, gallium oxide, barium oxide, etc., may be used for the light transmitting material layer.

Again, referring to FIG. 1, after forming the optical guides 172 as above, a protective layer 180 comprising a silicon oxide (e.g., silane-based silicon dioxide) may be formed on the third interlayer insulating layer 154 and the optical guides 172. According to one or more embodiments of the present invention, after forming the protective layer 180, an annealing process may be performed to reduce dark current (e.g., in the photodiode). Especially, the annealing process may be performed to cure defect sites such as plasma damage resulting from etching processes performed on the substrate (e.g., epitaxial layer 102A) and/or dangling bonds at the surface of the substrate 102/102A that may result from ion implantation.

Moreover, if the first insulating layer 130 is excessively etched during the anisotropic etching process for forming the openings 170, dark current may result from plasma damage to the substrate or epitaxial layer 102A. However, according to one or more embodiments of the present invention, excessive etching or overetching of the first insulating layer 130 may be prevented by the etch stop layer 140 (which allows a separate, and more uniform, etch of the first insulating layer 130), and thus the thickness of the first insulating layer 130 may be maintained and/or made more uniform. As a result, dark current (e.g., due to plasma damage) may be reduced.

A color filter 182 may be formed on the protective layer 180. Then, a planarization layer 184 may be formed on the color filter layer 182. Also, micro lenses 186 may be formed on the planarization layer 184.

The above CMOS image sensor 100 may include a logic region connected to the pixel regions.

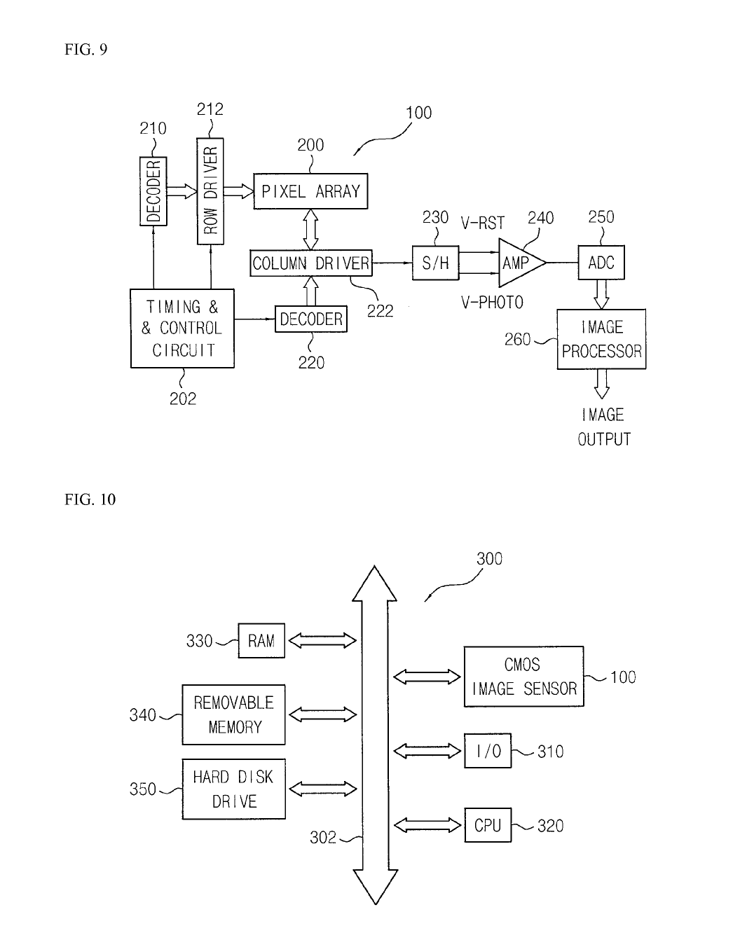

FIG. 9 is a schematic and/or block diagram illustrating an operation of the CMOS image sensor shown in FIG. 1.

Referring to FIG. 9, the CMOS image sensor 100 may include a plurality of pixel regions. The pixel regions may be arranged in a predetermined number of columns and rows.

Rows of pixels in a pixel array 200 (or in a region thereof) may be read out one by one. Accordingly, pixels in a row of the pixel array 200 may be selected simultaneously to be read out. Additionally or alternatively, signals indicating light received from the selected pixels may be selectively read out on or by a column select line.

A row line in the pixel array 200 may be selectively activated by a row address decoder 210 and a row driver 212. A column select line may be selectively activated by a column address decoder 220 and a column driver 222. The pixel array 200 may be operated by the timing and control circuit 202, which controls the address decoders 210 and 220 to select a predetermined, proper and/or appropriate row and column for pixel signal read-out.

The signals on the column read-out lines typically include a pixel reset signal V-rst and a pixel image signal V-photo for each pixel. Both signals are read into a sample and hold circuit (S/H) 230 in response to the column driver 222. A differential signal Vrst-Vphoto for each pixel is produced by a differential amplifier (AMP) 240 and each pixel's differential signal is digitized by an analog to digital converter (ADC) 250. The analog to digital converter 250 supplies the digitized pixel signals to an image processor 260, and then the image processor 250 processes the digitized pixel signals and provides digital signals defining an image output.

FIG. 10 is a block diagram illustrating a processor based system including the CMOS image sensor of FIG. 9.

Referring to FIG. 10, the processor based system 300 may include a digital circuit including the CMOS image sensor 100. For example, the processor based system 300 may include a computer system, a camera system, a scanner, a machine vision system, a vehicle navigation system, a video phone, a surveillance system, an auto focus system, star tracker systems, a motion detection system, and/or any other system that acquires one or more images.

The processor based system 300, for example, a camera system, typically includes a central processing unit (CPU) 320 such as a microprocessor communicating with an input/output (I/O) device 310 over or through a bus 302. The CMOS image sensor 100 communicates with the CPU 320 over or through the bus 302. The processor based system 300 includes a random access memory (RAM) 330, and also may include a removable memory 340, such as flash memory, and a hard disk drive 350 communicating with the CPU 320 over or through the bus 302.

According to the above-mentioned embodiments of the present invention, the etch stop layer 140 may be formed on the first insulating layer 130, which is in turn on the photodiodes 120 and the transistors 110, and the second insulating layer 142 may be formed on the etch stop layer 140. Accordingly, when the second insulating layer 142 is patterned to form trenches for the signal lines 146, etch uniformity of the second insulating layer across an entire substrate 142 may be greatly improved by the etch stop layer 140.

Especially, the depth uniformity of the trenches 144 for forming the signal lines 146 may be improved, and thus the thickness and electrical resistance of the signal lines 146 may become more uniform.

Additionally, the etch stop layer 140 may be subsequently used again during an anisotropic etching process for forming the optical guide 172, and thus the height of the optical guide 172 and the thickness of the first insulating layer 130 may be maintained and/or more uniform. As a result, the optical characteristics of CMOS image sensors 100 on the substrate 102 may be improved.

Although the CMOS image sensor and the method of manufacturing the same have been described with reference to specific embodiments, they are not limited thereto. Therefore, it will be readily understood by those skilled in the art that various modifications and changes can be made thereto without departing from the spirit and scope of the present invention defined by the appended claims.

What is claimed is:

1. A complementary metal-oxide-semiconductor (CMOS) image sensor comprising:
a substrate including a photodiode;
a transistor on the substrate;
a first insulating layer on the substrate;
a contact connected to the transistor and passing through the first insulating layer;
an etch stop layer on the first insulating layer;
a second insulating layer on the etch stop layer; and
a signal line extending through the etch stop layer and the second insulating layer, on the first insulating layer and connected to the contact.

2. The sensor of claim 1, wherein the etch stop layer comprises silicon nitride.

3. The sensor of claim 1, wherein the etch stop layer has a thickness of about 200 Å to about 400 Å.

4. The sensor of claim 1, further comprising:
a plurality of further insulating layers on the second insulating layer; and
at least one wiring layer between each of the further insulating layers.

5. The sensor of claim 3, further comprising an optical guide on the first insulating layer, the optical guide passing through the further insulating layers, the second insulating layer and the etch stop layer, and corresponding to the photodiode.

6. The sensor of claim 5, further comprising:
a protective layer on the optical guide;
a color filter layer on the protective layer;
a planarization layer on the color filter layer; and
a micro lens on the planarization layer.

7. The sensor of claim 5, wherein the optical guide comprises a metal oxide having a higher refractive index than a material of the further insulating layers.

8. A method of manufacturing a CMOS image sensor, the method comprising:
forming a photodiode in or on a substrate and a transistor on the substrate;
forming a first insulating layer on the photodiode and the transistor;
forming a contact connected to the transistor through the first insulating layer;
sequentially forming an etch stop layer and a second insulating layer on the first insulating layer and the contact;
forming a trench exposing the contact; and
forming a signal line by filling the trench.

9. The method of claim 8, wherein the etch stop layer comprises silicon nitride.

10. The method of claim 8, wherein the etch stop layer has a thickness of about 200 Å to about 400 Å.

11. The method of claim 8, wherein the first insulating layer has a thickness of about 4000 Å.

12. The method of claim 8, further comprising:
forming a plurality of further insulating layers on the second insulating layer and the signal line; and
forming at least one wiring layer on a lower one of the further insulating layers.

13. The method of claim 12, further comprising:
forming an opening exposing the first insulating layer by removing the further insulating layers, the second insulating layer and the etch stop layer in a predetermined region, the opening corresponding to the photodiode; and
forming an optical guide by filling the opening with a light transmitting material.

14. The method of claim 13, further comprising:
forming a protective layer on the optical guide;
forming a color filter on the protective layer;
forming a planarization layer on the color filter layer; and
forming a micro lens on the planarization layer.

15. The method of claim 13, wherein the optical guide comprises a metal oxide having a higher refractive index than a material of the further insulating layers.

16. The method of claim 8, further comprising forming a p-type region at or in a surface portion of the substrate before forming the photodiode and the transistor.

17. A method of manufacturing a CMOS image sensor, the method comprising:
forming a photodiode in or on a substrate and a transistor on the substrate;
sequentially forming a first insulating layer, an etch stop layer and a second insulating layer on the photodiode and the transistor;
forming a trench exposing the first insulating layer by removing the second insulating layer and the etch stop layer in a predetermined area;
forming a contact hole exposing the transistor by removing a portion of the exposed first insulating layer; and
forming a contact and a signal line connected to the transistor by filling the contact hole and the trench with a conductive material.
